(19) United States
(12) Patent Application Publication
(10) Pub. No.: US 2024/0199659 A1
(43) Pub. Date: Jun. 20, 2024

(54) CYCLOALKYLNORBORNENE COMPOUNDS WITH HETEROCYCLIC FUNCTIONALITY FOR VOC-FREE CROSSLINKING AND SURFACE FUNCTIONALIZATION

(71) Applicant: Gelest, Inc., Morrisville, PA (US)

(72) Inventors: Chad Michael BRICK, Yardley, PA (US); Richard J. Liberatore, Durham, NC (US); Michael John Watson, Warrington, PA (US)

(21) Appl. No.: 18/524,035

(22) Filed: Nov. 30, 2023

Related U.S. Application Data
(60) Provisional application No. 63/429,193, filed on Dec. 1, 2022.

(51) Int. Cl. C07F 7/30; B05D 1/00; C07F 7/08; C07F 7/10; C07F 7/22

(52) U.S. Cl. CPC C07F 7/30; B05D 1/60; C07F 7/0834; C07F 7/0898; C07F 7/10; C07F 7/2284

(57) ABSTRACT

A series of norbornene compounds having heterocyclic functionality are described, as well as methods for their preparation. Also described are rapid, low-temperature, low-(VOC)-methods for attaching these norbornene compounds to surfaces for use as chemical attachment points for a variety of functional molecules.

### CROSS-REFERENCE TO RELATED APPLICATIONS

This application claims priority to co-pending U.S. Provisional Application No. 63/429,193, filed Dec. 1, 2022, the disclosure of which is herein incorporated by reference in its entirety.

### BACKGROUND OF THE INVENTION

Norbornene units have long been utilized to impart superior properties to polymer systems due to their rigid structure, which results in the high glass transition temperatures that are critical in many applications. Additionally, norbornene units have highly specific reactivity which differs from chemically similar compounds, such as vinyl or allyl groups, and has been exploited, for example, in the attachment of reactive polymers to glass or polymer substrates for use in biomolecular detection, proteomics, and nucleic acid sequencing. The ability to easily attach norbornene-containing compounds to surfaces via a rapid, low temperature, low-VOC process would reduce environmental impacts, material consumption, and capital costs while affording the ability to create norbornene functionality on substrates whose temperature stability is limited.

### BRIEF SUMMARY OF THE INVENTION

In one embodiment, aspects of the disclosure relate to a norbornene compound having formula (I), formula (II), formula (III), formula (IV), formula (V) or formula (VI):

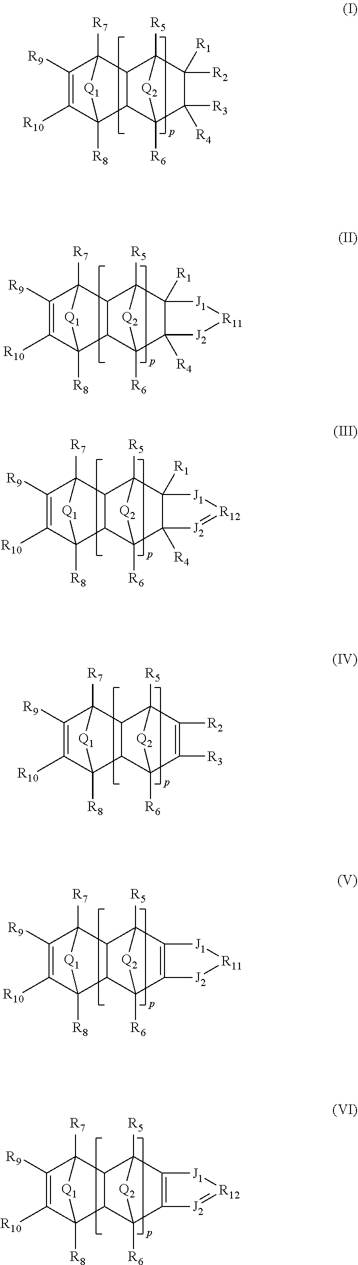

wherein p is 0, 1 or 2; Q₁ and Q₂ are independently O, S, N(R₁₃), C═O, C(R₁₄)(R₁₅) or (R₁₄)(R₁₅)C—C—(R₁₆)(R₁₇); J₁ and J₂ are independently O, S, N(R₁₈), C═O, or C(R₁₉)(R₂₀); J₃ is N or C(R₁₉);
R₁₁ is an (C5-C12)aliphatic group, (C5-C12)heterocyclic group, or (C6-C14)aromatic group bonded to both J₁ and J₂ or has formula [T]:

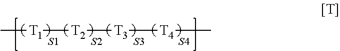

wherein T₁, T₂, T₃, and T₄ are each independently selected from O, S, N(R₂₁), C═O and C(R₂₂)(R₂₃), each of S₁, S₂, S₃, and S₄ is 0 or 1, provided that S₁+S₂+S₃+S₄>0; and wherein if S₁+S₂+S₃+S₄≥2, [T] is a bidentate ligand bonded to both J₁ and J₂;
R₁₂ a (C5-C12)aliphatic group or a (C5-C12)heterocyclic group bonded to both J₃ and J₂ or has formula [U]:

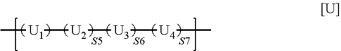

wherein U₁ is N or C(R₂₂); U₂, U₃, and U₄ are each independently selected from O, S, N(R₂₁), C═O and C(R₂₂)(R₂₃) and each of S₅, S₆, and S₇ is 0 or 1; wherein if S₅+S₆+S₇≥1, [U] is a bidentate ligand bonded to both J₁ and J₃;
R₁, R₂, R₃, R₄, R₅, R₆, R₇, R₈, R₉, R₁₀, R₁₃, R₁₄, R₁₅, R₁₆, R₁₇, R₁₈, R₁₉, R₂₀, R₂₁, R₂₂ and R₂₃ are the same or different and are each independently selected from the group consisting of a single bond, hydrogen, halogen, hydroxy, methyl, ethyl, methoxy, ethoxy, linear or branched (C₃-C₁₈)alkyl, (C₂-C₁₈)alkenyl, (C₃-C₁₈)alkoxy, tri(C₁-C₆)alkylsilyl, tri(C₁-C₆)alkoxysilyl, di(C₁-C₆)alkylamino, di(C₁-C₆)alkyl(C₁-C₆)alkylamino, perfluoro(C₁-C₁₈)alkyl, (C₃-C₁₂)cycloalkyl, (C₆-C₁₂)bicyclo(C₁-C₆)alkyl, (C₇-C₁₄)tricyclo(C₁-C₆)alkyl, (C₁-C₁₈)thioalkyl, (C₂-C₆)acyl, (C₂-C₈)acyloxy, (C₆-C₁₄)aryl, (C₆-C₁₄)aryl(C₁-C₈)alkyl, perfluoro(C₆-C₁₄)aryl, perfluoro(C₆-C₁₄)aryl(C₁-C₃)alkyl, (C₆-C₁₄)aryloxy, (C₆-C₁₄)aryl(C₁-C₆)alkoxy, (C₁-C₁₂)alkyl(C₁- C₁₂)perfluoro, and at least one of R₁, R₂, R₃, R₄, R₅, R₆, R₇, R₈, R₉, R₁₀, R₁₃, R₁₄, R₁₅, R₁₆, R₁₇, R₁₈, R₁₉, R₂₀, R₂₁, R₂₂ and R₂₃ comprises or is substituted with a heterocyclic group having formula (A), formula (B), formula (C), formula (D), formula (E), formula (F), formula (G), or formula (H):

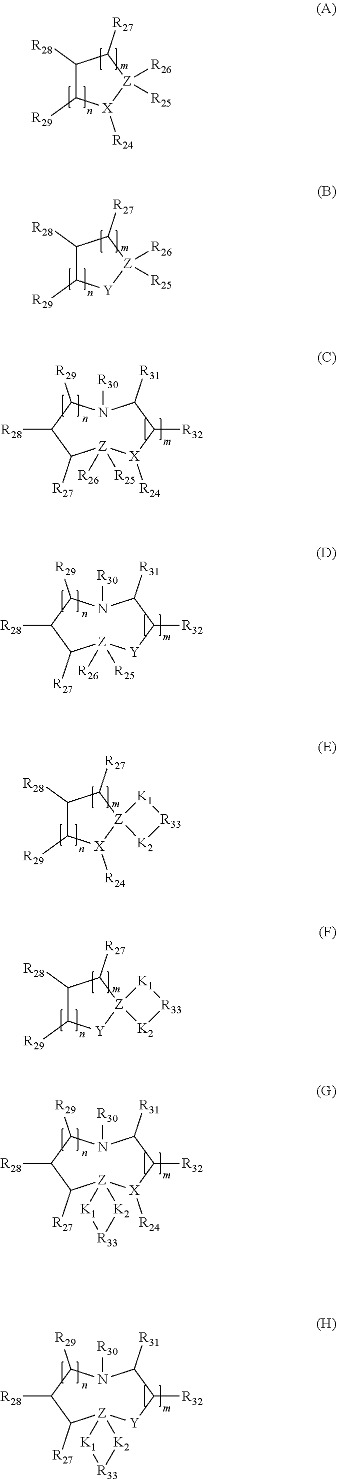

wherein Z is a Group 14 element other than carbon; X is a Group 15 element; Y is a Group 16 element; m and n are each independently an integer from 1 to 10; K₁ and K₂ are independently O, S, N(R₃₄), or C(R₃₅)(R₃₆); R₃₃ is an (C5-C12)aliphatic group, a (C5-C12)heterocyclic, a (C6-C14)aromatic group bonded to both J₁ and J₂, or has formula [W]:

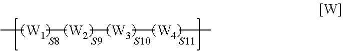

wherein W₁, W₂, W₃, and W₄ are each independently selected from O, S, N(R₃₇), C═O and C(R₃₉)(R₃₉), each of S₈, S₉, S₁₀, and S₁₁ is 0 or 1, provided that S₈+S₉+S₁₀+S₁₁>0; wherein if S₈+S₉+S₁₀+S₁₁≥2, [W] is a bidentate ligand bonded to both K₁ and K₂;
R₂₄, R₂₅, R₂₆, R₂₇, R₂₈, R₂₉, R₃₀, R₃₁, R₃₂, R₃₄, R₃₅, R₃₆, R₃₇, R₃₈, and R₃₉ are the same or different and are each independently a single bond, hydrogen, halogen, hydroxy, methyl, ethyl, methoxy, ethoxy, linear or branched (C₃-C₁₈)alkyl, (C₂-C₁₈)alkenyl, (C₃-C₁₈)alkoxy, tri(C₁-C₆)alkylsilyl, tri(C₁-C₆)alkoxysilyl, di(C₁-C₆)alkylamino, di(C₁-C₆)alkyl(C₁-C₆)alkylamino, perfluoro(C₁-C₁₈)alkyl, (C₃-C₁₂)cycloalkyl, (C₆-C₁₂)bicyclo(C₁-C₆)alkyl, (C₇-C₁₄)tricyclo(C₁-C₆)alkyl, (C₁-C₁₈)thioalkyl, (C₂-C₆)acyl, (C₂-C₈)acyloxy, (C₆-C₁₄)aryl, (C₆-C₁₄)aryl(C₁-C₈)alkyl, perfluoro(C₆-C₁₄)aryl, perfluoro(C₆-C₁₄)aryl(C₁-C₃)alkyl, (C₆-C₁₄)aryloxy, (C₆-C₁₄)aryl(C₁-C₆)alkoxy, or (C₁-C₁₂)alkyl(C₁-C₁₂)perfluoro; where at least one of R₂₄, R₂₅, R₂₆, R₂₇, R₂₈, R₂₉, R₃₀, R₃₁, R₃₂, R₃₄, R₃₅, R₃₆, R₃₇, R₃₈, and R₃₉ is a single bond connecting to a structure of formula (I), formula (II), formula (III), formula (IV), formula (V) or formula (VI).

### DETAILED DESCRIPTION OF THE INVENTION

Aspects of the disclosure relate to a series of norbornene compounds having heterocyclic functionality and to a rapid, volatile organic compound (VOC)-free or reduced-VOC method for attaching these norbornene compounds to surfaces. In some embodiments, the disclosure relates to a series of cyclic azasilane and thiasilane compounds, having utility as VOC-free or VOC-reduced, rapid, and selective surface functionalization agents via the norbornene functionality or heterocyclic functionality.

Unless otherwise stated, any numerical value set forth herein is to be understood as being modified in all instances by the term “about.” Thus, a numerical value typically includes ±10% of the recited value. For example, the recitation of a temperature such as “10° C.” or “about 10° C.” includes 9° C. and 11° C. and all temperatures therebetween. Further, all numerical ranges expressed in this disclosure expressly encompass all possible subranges, all individual numerical values within that range, including integers within such ranges and fractions and decimal amounts of the values unless the context clearly indicates otherwise. All ranges of carbon chain lengths may be understood to encompass all carbon chain lengths within the recited range. For example, “linear or branched (C3-C18)alkyl” may be understood to refer to all linear and branched alkyl groups having 3, 4, 5, 6, 7, 8, 9, 10, 11, 12, 13, 14, 15, 16, 17, or 18 carbon atoms.

### Norbornene Compounds

As described in more detail below, aspects of the disclosure relate to norbornene-containing compounds containing heterocyclic groups, which may be suitable for the formation of surfaces comprising norbornene functionality. Norbornenes are highly strained bridged cyclic hydrocarbons consisting of a cyclohexene ring with a methylene bridge between carbons 1 and 4. The simplest norbornene compound, bicyclo[2.2.1] hept-2-ene, has the following structure (two different depictions of the same molecule are shown:

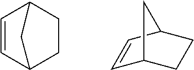 [SMILES: C1=CC2CCC1C2 ; C1=CC2CCC1C2]

More broadly, the disclosure relates to norbornene compounds having formula (I), formula (II), formula (III), formula (IV), formula (V), or formula (VI):

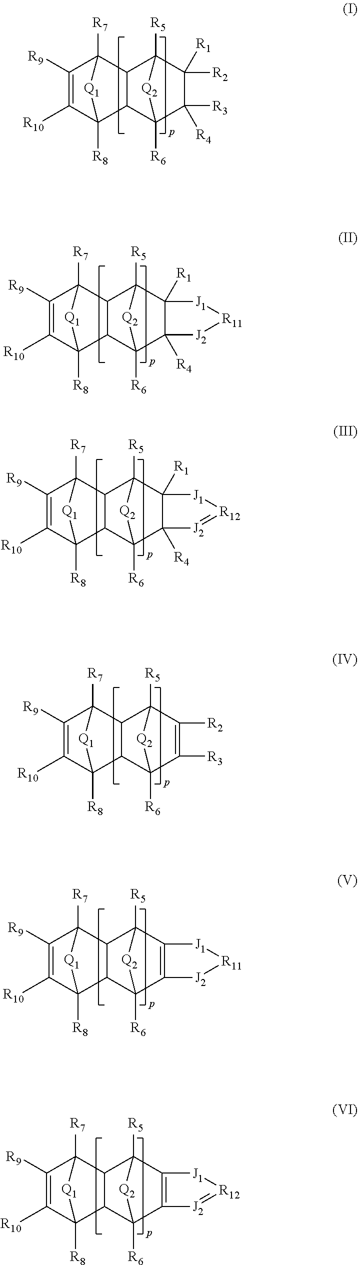

In formulas (I), (II), (III), (IV), (V), and (VI), p is 0, 1 or 2; Q₁ and Q₂ are independently O, S, N(R₁₃), C═O, C(R₁₄)(R₁₅) or (R₁₄)(R₁₅)C—C—(R₁₆)(R₁₇); J₁ and J₂ are independently O, S, N(R₁₈), C═O, or C(R₁₉)(R₂₀); J₃ is N or C(R₁₉);
R₁₁ is an (C5-C12)aliphatic group, (C5-C12)heterocyclic group, or (C6-C14)aromatic group bonded to both J₁ and J₂ or has formula [T]:

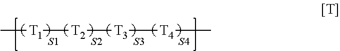

wherein T₁, T₂, T₃, and T₄ are each independently selected from O, S, N(R₂₁), C═O and C(R₂₂)(R₂₃), each of S₁, S₂, S₃, and S₄ is 0 or 1, provided that S₁+S₂+S₃+S₄>0; and wherein if S₁+S₂+S₃+S₄≥2, [T] is a bidentate ligand bonded to both J₁ and J₂;
R₁₂ a (C5-C12)aliphatic group or a (C5-C12)heterocyclic group bonded to both J₃ and J₂ or has formula [U]:

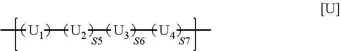

wherein U₁ is N or C(R₂₂); U₂, U₃, and U₄ are each independently selected from O, S, N(R₂₁), C═O and C(R₂₂)(R₂₃) and each of S₅, S₆, and S₇ is 0 or 1; wherein if S₅+S₆+S₇≥1, [U] is a bidentate ligand bonded to both J₁ and J₃;
R₁, R₂, R₃, R₄, R₅, R₆, R₇, R₈, R₉, R₁₀, R₁₃, R₁₄, R₁₅, R₁₆, R₁₇, R₁₈, R₁₉, R₂₀, R₂₁, R₂₂ and R₂₃ are the same or different and are each independently selected from the group consisting of a single bond, hydrogen, halogen, hydroxy, methyl, ethyl, methoxy, ethoxy, linear or branched (C₃-C₁₈)alkyl, (C₂-C₁₈)alkenyl, (C₃-C₁₈)alkoxy, tri(C₁-C₆)alkylsilyl, tri(C₁-C₆)alkoxysilyl, di(C₁-C₆)alkylamino, di(C₁-C₆)alkyl(C₁-C₆)alkylamino, perfluoro(C₁-C₁₈)alkyl, (C₃-C₁₂)cycloalkyl, (C₆-C₁₂)bicyclo(C₁-C₆)alkyl, (C₇-C₁₄)tricyclo(C₁-C₆)alkyl, (C₁-C₁₈)thioalkyl, (C₂-C₆)acyl, (C₂-C₈)acyloxy, (C₆-C₁₄)aryl, (C₆-C₁₄)aryl(C₁-C₈)alkyl, perfluoro(C₆-C₁₄)aryl, perfluoro(C₆-C₁₄)aryl(C₁-C₃)alkyl, (C₆-C₁₄)aryloxy, (C₆-C₁₄)aryl(C₁-C₆)alkoxy, (C₁-C₁₂)alkyl(C₁- C₁₂)perfluoro, and at least one of R₁, R₂, R₃, R₄, R₅, R₆, R₇, R₈, R₉, R₁₀, R₁₃, R₁₄, R₁₅, R₁₆, R₁₇, R₁₈, R₁₉, R₂₀, R₂₁, R₂₂ and R₂₃ comprises or is substituted with a heterocyclic group having formula (A), formula (B), formula (C), formula (D), formula (E), formula (F), formula (G), or formula (H):

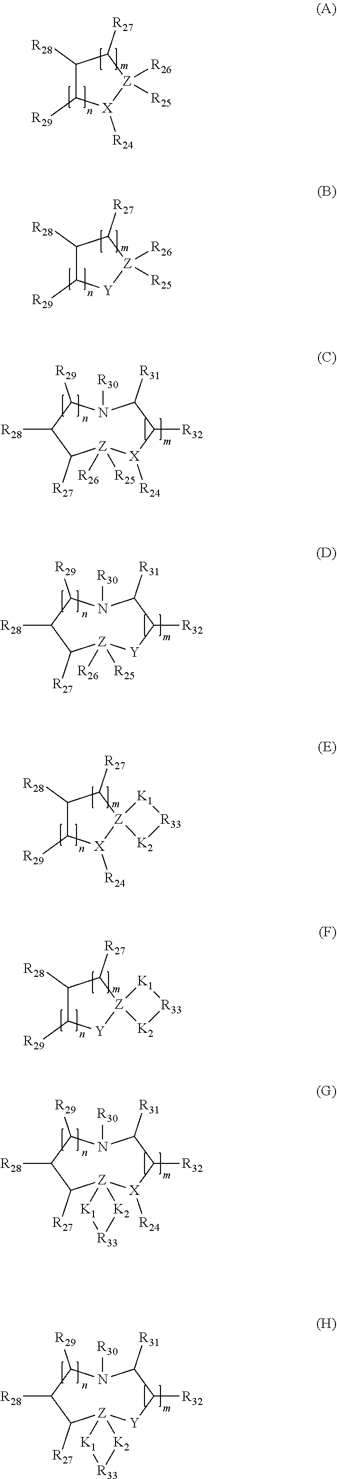

Z is a Group 14 element other than carbon; X is a Group 15 element; Y is a Group 16 element; m and n are each independently an integer from 1 to 10; K₁ and K₂ are independently O, S, N(R₃₄), or C(R₃₅)(R₃₆); R₃₃ is an (C5-C12)aliphatic group, a (C5-C12)heterocyclic, a (C6-C14)aromatic group bonded to both J₁ and J₂, or has formula [W]:

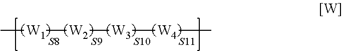

wherein W₁, W₂, W₃, and W₄ are each independently selected from O, S, N(R₃₇), C═O and C(R₃₉)(R₃₉), each of S₈, S₉, S₁₀, and S₁₁ is 0 or 1, provided that S₈+S₉+S₁₀+S₁₁>0; wherein if S₈+S₉+S₁₀+S₁₁≥2, [W] is a bidentate ligand bonded to both K₁ and K₂;
R₂₄, R₂₅, R₂₆, R₂₇, R₂₈, R₂₉, R₃₀, R₃₁, R₃₂, R₃₄, R₃₅, R₃₆, R₃₇, R₃₈, and R₃₉ are the same or different and are each independently a single bond, hydrogen, halogen, hydroxy, methyl, ethyl, methoxy, ethoxy, linear or branched (C₃-C₁₈)alkyl, (C₂-C₁₈)alkenyl, (C₃-C₁₈)alkoxy, tri(C₁-C₆)alkylsilyl, tri(C₁-C₆)alkoxysilyl, di(C₁-C₆)alkylamino, di(C₁-C₆)alkyl(C₁-C₆)alkylamino, perfluoro(C₁-C₁₈)alkyl, (C₃-C₁₂)cycloalkyl, (C₆-C₁₂)bicyclo(C₁-C₆)alkyl, (C₇-C₁₄)tricyclo(C₁-C₆)alkyl, (C₁-C₁₈)thioalkyl, (C₂-C₆)acyl, (C₂-C₈)acyloxy, (C₆-C₁₄)aryl, (C₆-C₁₄)aryl(C₁-C₈)alkyl, perfluoro(C₆-C₁₄)aryl, perfluoro(C₆-C₁₄)aryl(C₁-C₃)alkyl, (C₆-C₁₄)aryloxy, (C₆-C₁₄)aryl(C₁-C₆)alkoxy, or (C₁-C₁₂)alkyl(C₁-C₁₂)perfluoro; where at least one of R₂₄, R₂₅, R₂₆, R₂₇, R₂₈, R₂₉, R₃₀, R₃₁, R₃₂, R₃₄, R₃₅, R₃₆, R₃₇, R₃₈, and R₃₉ is a single bond connecting to a structure of formula (I), formula (II), formula (III), formula (IV), formula (V) or formula (VI).

In formula (I), formula (II), formula (III), formula (IV), formula (V), and formula (VI), Q₁ and Q₂ form the bridge of the norbornene structure and are, preferably without limitation, CH₂, C(CH₃)₂, O, N(CH₃), and CH₂—CH₂; p is 0, 1, or 2, R₁, R₂, R₃, R₄, R₅, R₆, R₇, R₈, R₉, R₁₀, R₁₃, R₁₄, R₁₅, R₁₆, R₁₇, R₁₈, R₁₉, R₂₀, R₂₁, R₂₂, and R₂₃ are independently, preferably, without limitation, a single bond, hydrogen, methyl, vinyl, ethyl, n-propyl, or n-butyl, with the provision that at least one of R₁, R₂, R₃, R₄, R₆, R₇, R₈, R₉, R₁₀, R₁₃, R₁₄, R₁₅, R₁₆, R₁₇, R₁₈, R₁₉, R₂₀, R₂₁, R₂₂ must comprise or be substituted with a heterocyclic group of formula (A), formula (B), formula (C), formula (D), formula (E), formula (F), formula (G), or formula (H); J₁ and J₂ are preferably independently NH, N(CH₃), O, or CH₂, and J₃ is preferably N, CH, or C(CH₃).

In the most preferred embodiments, the norbornene compound has formula (I), Q₁ is CH₂, p=0, and R₁, R₂, R₃, R₄, R₅, R₆, R₇, R₈, R₉, R₁₀ are hydrogen, with the provision that one of R₁, R₂, R₃, and R₄ is not hydrogen and comprises or is substituted with a heterocyclic group of formula (A), formula (B), formula (C), formula (D), formula (E), formula (F), formula (G), or formula (H).

In formula (A), formula (B), formula (C), formula (D), formula (E), formula (F), formula (G), and formula (H), Z is a Group 14 element other than carbon, such as, without limitation, silicon, or germanium; X is a Group 15 element such as, without limitation, nitrogen or phosphorous; Y is a Group 16 element such as, without limitation, sulfur, selenium or tellurium. Thus, each of functional groups (A) to (H) contains a bond between a Group 14 element (Z) and either a group 15 element (X) or a group 16 element (Y).

In formula (A), formula (B), formula (C), formula (D), formula (E), formula (F), formula (G), and formula (H), R₂₄, R₂₇, R₂₈, R₂₉, R₃₀, R₃₁, R₃₂, R₃₄, R₃₅, R₃₆, R₃₇, R₃₈, and R₃₉ are independently, without limitation, preferably a single bond, hydrogen, methyl, ethyl, vinyl, isopropyl, n-propyl, allyl, n-butyl, sec-butyl, or t-butyl, and R₂₅ and R₂₆ are independently preferably a single bond, hydrogen, methyl, ethyl, methoxy, or ethoxy, with the provision that at least one of R₂₄, R₂₅, R₂₆, R₂₇, R₂₈, R₂₉, R₃₀, R₃₁, R₃₂, R₃₄, R₃₅, R₃₆, R₃₇, R₃₈, and R₃₉ must be a single bond connecting to a structure of formula (I), formula (II), formula (III), formula (IV), formula (V) or formula (VI).

In preferred embodiments, the structure of the heterocyclic component has formula (A) or formula (B), m=1 or 2, n=1 or 2, R₂₄, R₂₇, R₂₈, and R₂₉ are independently a single bond, hydrogen or methyl, R₂₅ and R₂₆ are a single bond, hydrogen, methyl, methoxy or ethoxy, Z is silicon, X is nitrogen and Y is sulfur.

In the most preferred embodiments, the structure of the heterocyclic component has formula (A), m=1, n=1, R₂₄, R₂₇, R₂₈, and R₂₉ are independently a single bond, hydrogen or methyl, R₂₅ and R₂₆ are a single bond, methyl, methoxy or ethoxy, Z is silicon and X is nitrogen.

In the case of compounds having formula (E), formula (F), formula (G), and formula (H), a bridging structure is formed by groups K₁, K₂, and R₃₃, which is a (C5-C12)aliphatic group, (C5- C12)heterocyclic group, or a (C6-C14)aromatic group bonded to both K₁ and K₂ or has formula [W] as defined above:

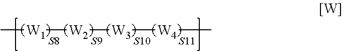

K₁ and K₂ are preferably independently selected from NH, N(CH₃), O, or CH₂.

In preferred compounds comprising formula (E), formula (F), formula (G), and formula (H), K₁ and K₂ are O, S8 and S9=1, S10 and S11=0, and W₁ and W₂ are CH₂, CH(CH₃) or C(CH₃)₂.

The difference between norbornene compounds having formulas (I) and (II) is that the former has four independent ligands R₁, R₂, R₃, and R₄ (typically two or three of which are hydrogen), whereas the latter contains a cyclic substituent (J₁-R₁₁-J₂) that consumes two of the ligand positions. The difference between formulas (II) and formula (III) is that J₃ has a double bond to the neighboring atom in R₁₂, while J₂ has a single bond to the neighboring atom of R₁₁.

Likewise, the difference between norbornene compounds having formulas (IV) and (V) is that the former has two independent ligands R₂ and R₃ whereas the latter contains a cyclic substituent (J₁-R₁₁-J₂) that consumes both of the ligand positions. The difference between formulas (V) and formula (VI) is that J₃ has a double bond to the neighboring atom in R₁₂, while J₂ has a single bond to the neighboring atom of R₁₁.

The difference between formulas (I), (II) and (III), and formulas (IV), (V), and (VI) is the presence of a double bond instead of the independent substituents R₁ and R₄.

Exemplary compounds having formula (I) in which p=0 and p=1 are shown below in formulas (VII) and (VIII), respectively. For the compound having formula (VII), the variables in formula (I) are as follows: p=0, Q₁=C(R₁₄)(R₁₅), R₁₄=R₁₅=H, m=n=1, R₂₅=R₂₆=CH₃, R₂₇=R₂₈=R₂₉=H, Z=Si, X=N, R₂, R₃, R₄, R₇, R₈, R₉, and R₁₀=H, R₁=a methyl group substituted with a compound having formula (A), and R₂₄ is a single bond connecting the heterocyclic group to the norbornene portion of the structure having Formula 1. For the compound having formula (VIII), the variables in formula (I) are as follows: p=1, Q₁=Q₂=C(R₁₄)(R₁₅), R₁₄=R₁₅=H, m=n=1, R₂₅=R₂₆=CH₃, R₂₇=R₂₈=R₂₉=H, Z=Si, X=N, R₂, R₃, R₄, R₅, R₆, R₇, R₈, R₉, and R₁₀=H, R₁=a methyl group substituted with a compound having formula (A), R₂₄ is a single bond connecting the heterocyclic group to the norbornene portion of the structure having Formula (I).

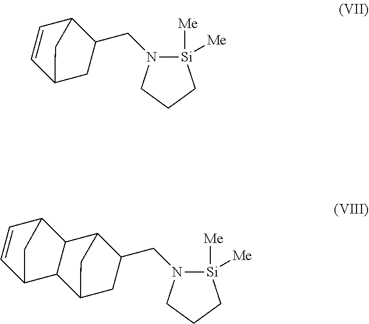 [SMILES: C[Si]1(C)CCCN1CC1CC2C=CC1C2 ; C[Si]1(C)CCCN1CC1CC2CC1C1C3C=CC(C3)C21]

Exemplary compounds having formula (II) or formula (III) in which J₁, J₂ and J₃ comprise carbon, nitrogen, and oxygen, are shown below in formulas (IX), (X), and (XI), respectively.

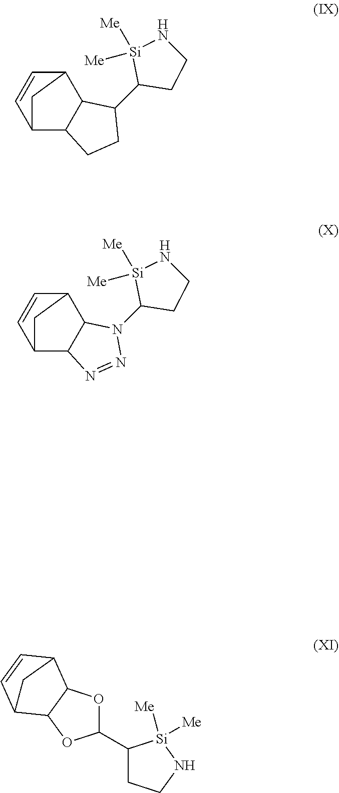 [SMILES: C[Si]1(C)NCCC1C1CCC2C3C=CC(C3)C21 ; C[Si]1(C)NCCC1N1N=NC2C3C=CC(C3)C21 ; C[Si]1(C)NCCC1C1OC2C3C=CC(C3)C2O1]

For the compound having formula (IX), the variables in compound (II) are as follows: p=0, Q₁=C(R₁₄)(R₁₅), R₁₄=R₁₅=H, J₁=CH(R₂₀), R₂₀ is a single bond connecting to a heterocycle of type A, J₂=CH₂, R₁₁=CH₂ (S1=1, S2=S3=S4=0, T₁=CH₂) m=n=1, Z=Si, X=N, R₂₅=R₂₆=CH₃; R₁, R₄, R₇, R₈, R₉, R₁₀, R₁₄, R₂₈ and R₂₉=H, and R₂₇=a single bond connecting to a compound having Formula (II). In Formula (X), p=0, Q₁=C(R₁₄)(R₁₅), R₁₄=R₁₅=H, J₁=N(R₁₈), R₁₈ is a single bond connecting to a heterocycle of type A, R₁₂=N (S5=S6=S7=0, U₁=N), R₂₅=R₂₆=CH₃; R₁, R₄, R₇, R₈, R₉, R₁₀, R₂₄, R₂₈ and R₂₉=H, and R₂₇=a single bond connecting to a compound having Formula (III). In formula (XI), p=0, Q₁=C(₁₄)(R₁₅), R₁₄=R₁₅=H, J₁=J₂=O, R₅=CH(R₂₃) (S1=1, S2=S3=S4=0, T₁=CH(R₂₃)), R₂₃=a single bond connecting to a heterocycle of type A, R₂₅=R₂₆=CH₃; R₁, R₄, R₇, R₈, R₉, R₁₀, R₂₄, R₂₈ and R₂₉=H and R₂₇=a single bond connecting to a compound having Formula (II).

Considering the heterocyclic portion of the norbornene compounds, there are three key variables in the core structure, leading to the eight possible functional groups having formulas (A) to (H).

A first variable is a simple cyclic versus a “silatrane,” a group containing a nitrogen atom in the chain which can form a weak bond with the Z atom (typically Si) and form the pseudo-double-ring structure in formulas (C), (D), (G), and (H). Functional groups (A), (B), (E), and (F) contain a simple cyclic group.

Examples of norbornene compounds containing a simple cyclic group (formula (A)) and a silatrane^{oo} group (formula (C)) are shown below in formulas (XII) and (XIII):

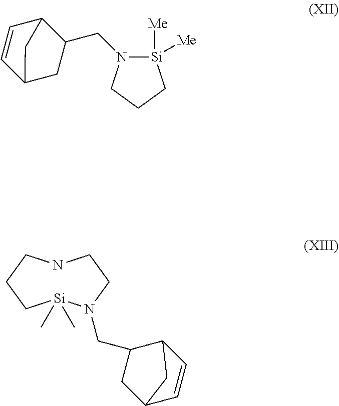 [SMILES: C[Si]1(C)CCCN1CC1CC2C=CC1C2 ; C[Si]1(C)CCCNCCN1CC1CC2C=CC1C2]

A second variable relates to the Z position (typically Si), which contains two bonds that are not part of the cyclic. These may be independent ligands such as, for example, alkoxy or alkyl, or a bidentate bridged structure that consumes both sites, as in groups (E) to (H).

An exemplary norbornene compound having a bidentate ligand and containing functional group (E) has formula (XIV). In formula (E), K₁ and K₂ are oxygen and R₃₃ is an (C6)aryl group bonded to both K₁ and K₂:

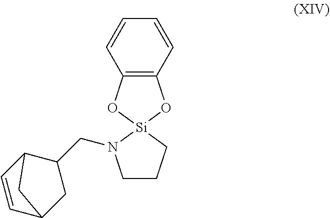 [SMILES: C1=CC2CC1CC2CN1CCC[Si]12Oc1ccccc1O2]

A third variable relates to the X/Y position (typically N or S), which differ in that in the case of N there is a third bond (R₁₄), while in the case of S or other Group 16 elements, there is no third bond. These differences are depicted in formulas (A) versus (B), (C) versus (D), etc. For example, compound (XV) below contains an X substituent (here, nitrogen), whereas compound (XVI) below contains a Y substituent (here, sulfur).

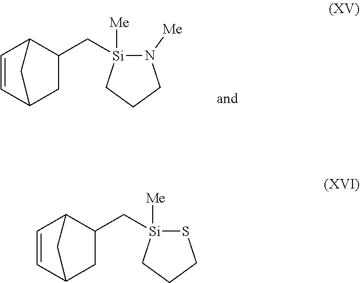 [SMILES: CN1CCC[Si]1(C)CC1CC2C=CC1C2 ; C[Si]1(CC2CC3C=CC2C3)CCCS1]

The compounds disclosed in this invention are comprised of a norbornene segment, as described in formula (I), formula (II), formula (III), formula (IV), formula (V) or formula (IV), where at least one of R₁, R₂, R₃, R₄, R₅, R₆, R₇, R₈, R₉, R₁₀, R₁₃, R₁₄, R₁₅, R₁₆, R₁₇, R₁₈, R₁₉, R₂₀, R₂₁, R₂₂ and R₂₃ comprises or is substituted with a heterocyclic group having formula (A), formula (B), formula (C), formula (D), formula (E), formula (F), formula (G), or formula (H). It shall be understood that “comprises” refers to the case where the heterocyclic group having formula (A), formula (B), formula (C), formula (D), formula (E), formula (F), formula (G), or formula (H) is directly singly bonded to the norbornene segment described in formula (I), formula (II), formula (III), formula (IV), formula (V) or formula (IV), connecting directly a position of R₁, R₂, R₃, R₄, R₆, R₇, R₈, R₉, R₁₀, R₁₃, R₁₄, R₁₅, R₁₆, R₁₇, R₁₈, R₁₉, R₂₀, R₂₁, R₂₂ and R₂₃ of the norbornene segments and R₂₄, R₂₅, R₂₆, R₂₇, R₂₈, R₂₉, R₃₀, R₃₁, R₃₂, R₃₄, R₃₅, R₃₆, R₃₇, R₃₈, and R₃₉ of the heterocyclic group. In this case, the norbornene group and the heterocyclic group may be considered to be directly bonded.

In the case where R₁, R₂, R₃, R₄, R₅, R₆, R₇, R₈, R₉, R₁₀, R₁₃, R₁₄, R₁₅, R₁₆, R₁₇, R₁₈, R₁₉, R₂₀, R₂₁, R₂₂ and R₂₃ comprises a heterocyclic group having formula (A), formula (B), formula (C), formula (D), formula (E), formula (F), formula (G), or formula (H), the connecting position R₁, R₂, R₃, R₄, R₅, R₆, R₇, R₈, R₉, R₁₀, R₁₃, R₁₄, R₁₅, R₁₆, R₁₇, R₁₈, R₁₉, R₂₀, R₂₁, R₂₂ or R₂₃ of the norbornene segment is comprised of methyl, ethyl, methoxy, ethoxy, linear or branched (C₃-C₁₈)alkyl, (C₂-C₁₈)alkenyl, (C₃-C₁₈)alkoxy, tri(C₁-C₆)alkylsilyl, tri(C₁-C₆)alkoxysilyl, di(C₁-C₆)alkylamino, di(C₁-C₆)alkyl(C₁-C₆)alkylamino, perfluoro(C₁-C₁₈)alkyl, (C₃-C₁₂)cycloalkyl, (C₆-C₁₂)bicyclo(C₁-C₆)alkyl, (C₇-C₁₄)tricyclo(C₁-C₆)alkyl, (C₁-C₁₈)thioalkyl, (C₂-C₆)acyl, (C₂-C₈)acyloxy, (C₆-C₁₄)aryl, (C₆-C₁₄)aryl(C₁-C₈)alkyl, perfluoro(C₆-C₁₄)aryl, perfluoro(C₆-C₁₄)aryl(C₁- C₃)alkyl, (C₆-C₁₄)aryloxy, (C₆-C₁₄)aryl(C₁-C₆)alkoxy, (C₁-C₁₂)alkyl(C₁-C₁₂)perfluoro, where a single bond exists between the R group and position R₂₄, R₂₅, R₂₆, R₂₇, R₂₈, R₂₉, R₃₀, R₃₁, R₃₂, R₃₄, R₃₅, R₃₆, R₃₇, R₃₈, and R₃₉ of the heterocyclic group at any chemically suitable position on the R group. In this case, the norbornene group and the heterocyclic group may be considered to be bonded through a bridging group comprising R₁, R₂, R₃, R₄, R₅, R₆, R₇, R₈, R₉, R₁₀, R₁₃, R₁₄, R₁₅, R₁₆, R₁₇, R₁₈, R₁₉, R₂₀, R₂₁, R₂₂ or R₂₃.

Formula (XVII), formula (XVIII), formula (XIX) and formula (XX) shown below depict the distinction between directly bonded norbornene and heterocyclic group and those bonded through a bridging group. In directly bonded formula (XVII), a single bond exists between position R₄ of the norbornene group of formula (I) and the R₂₄ position on the nitrogen atom of a heterocyclic group of formula (A), while in directly bonded formula (XVIII), a single bond exists between position R₁₄ of the norbornene group of formula (I) and the R₂₅ position on the silicon atom of a heterocyclic group of formula (A).

In formula (XIX) and formula (XX), examples of bonding through bridging groups are depicted. In bridge bonded formula (XIX), a methyl group substituted with a heterocyclic group of formula (A) exists at position R₁ of the norbornene group, where the methyl group is singly bonded to position R₂₄ on the nitrogen atom of the heterocyclic group. In bridge bonded formula (XX), a (C6)aryl (phenyl) group exists at position R₄ of the norbornene group, and this (C6)aryl group is substituted at a meta position with a heterocyclic group of formula (A), where the (C6)aryl group is singly bonded to position R₂₇ to a carbon atom of the heterocyclic group.

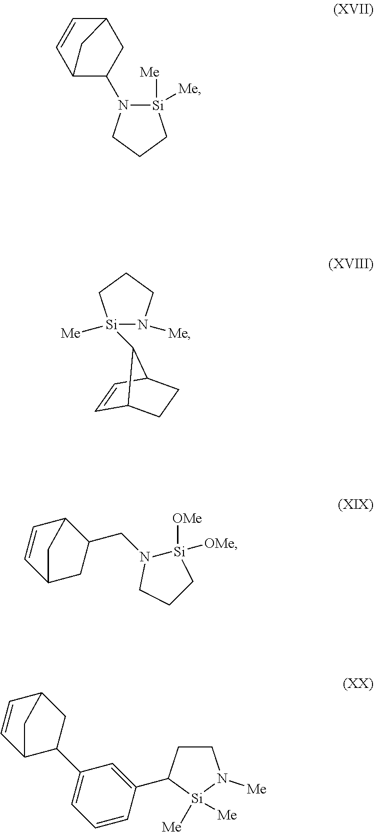 [SMILES: C[Si]1(C)CCCN1C1CC2C=CC1C2 ; CN1CCC[Si]1(C)C1C2C=CC1CC2 ; CO[Si]1(OC)CCCN1CC1CC2C=CC1C2 ; CN1CCC(c2cccc(C3CC4C=CC3C4)c2)[Si]1(C)C]

The compounds disclosed herein may have more than one heterocyclic group of formula (A), formula (B), formula (C), formula (D), formula (E), formula (F), formula (G), or formula (H), as depicted in formula (XXI), shown below, or more than one norbornene group of formula (I) formula (II), formula (III), formula (IV), formula (V) or formula (IV), as depicted in formula (XXII), shown below. In compounds with more than one heterocyclic group, they may be the same or different and bonded to one or more norbornene group at positions defined above. Likewise, in compounds with more than one norbornene group, the norbornene groups may be the same or different and bonded to one or more heterocyclic groups at positions defined above.

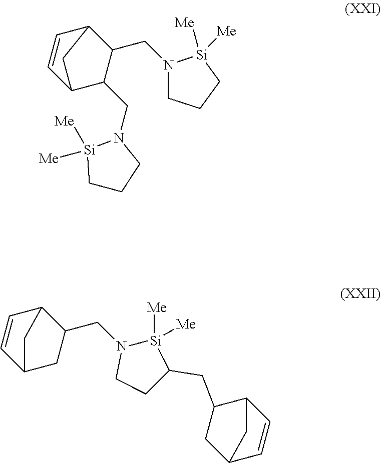 [SMILES: C[Si]1(C)CCCN1CC1C2C=CC(C2)C1CN1CCC[Si]1(C)C ; C[Si]1(C)C(CC2CC3C=CC2C3)CCN1CC1CC2C=CC1C2]

Representative examples of norbornene-heterocyclic compounds in accordance with aspects of the disclosure are shown below.

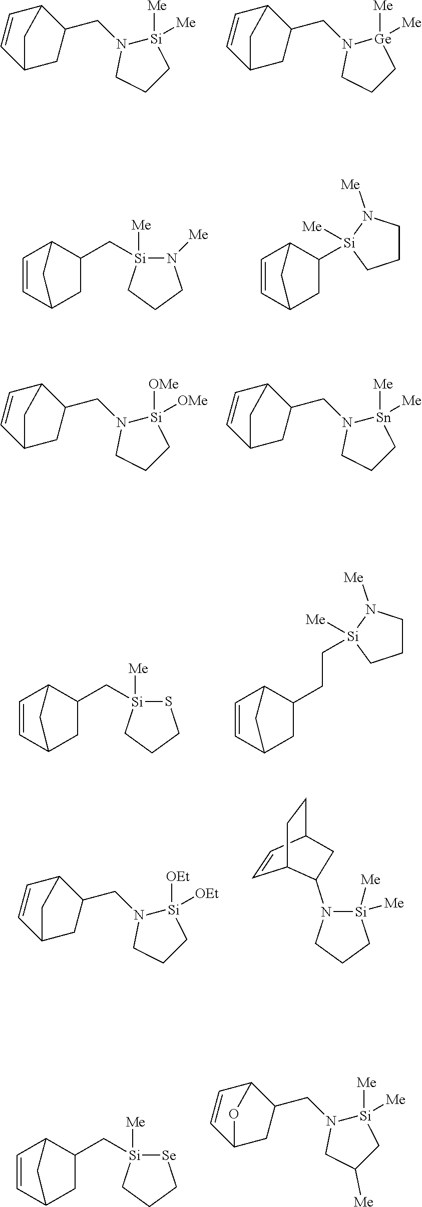

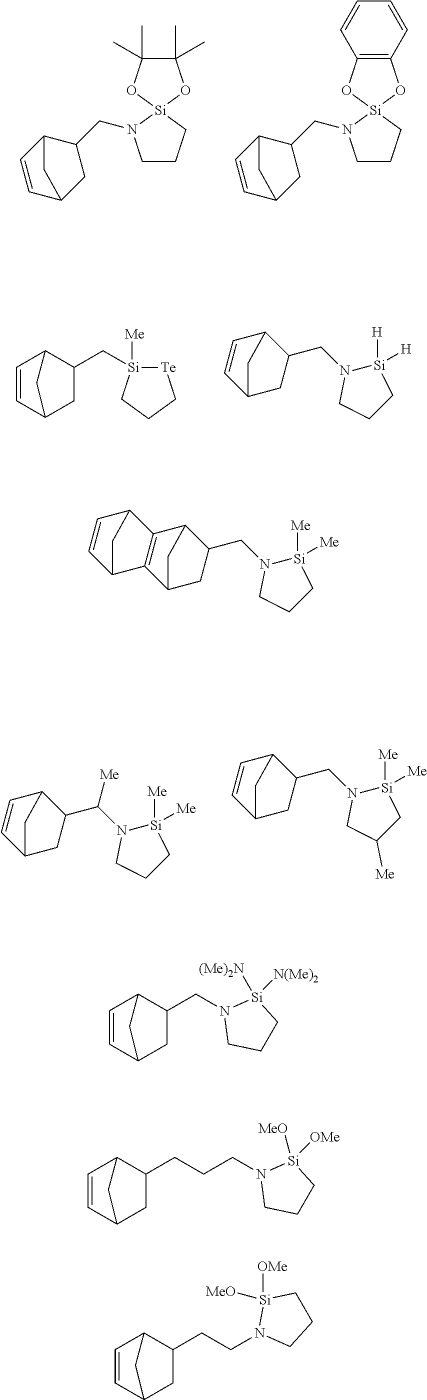

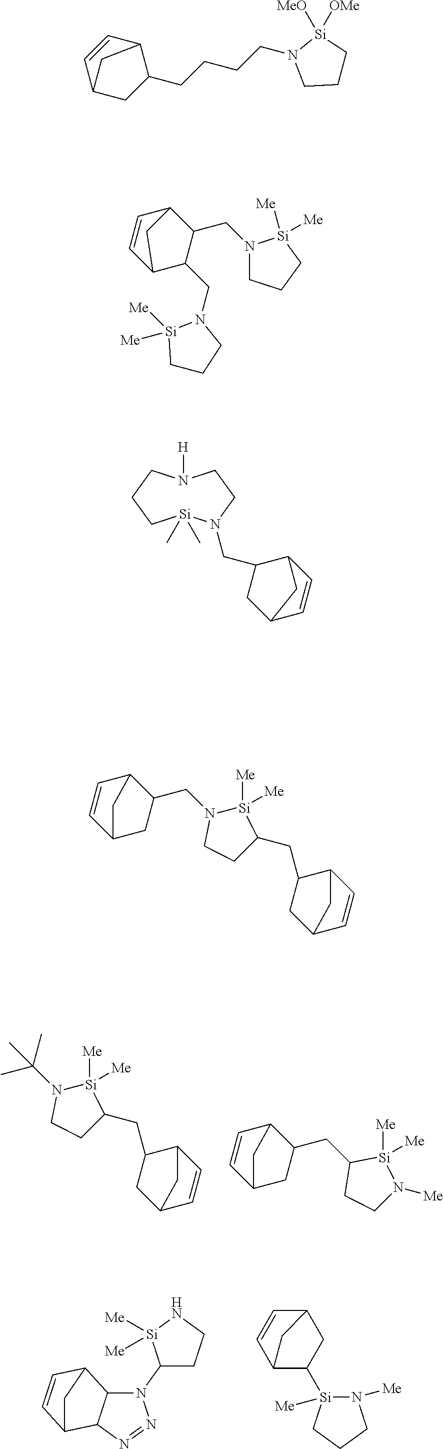

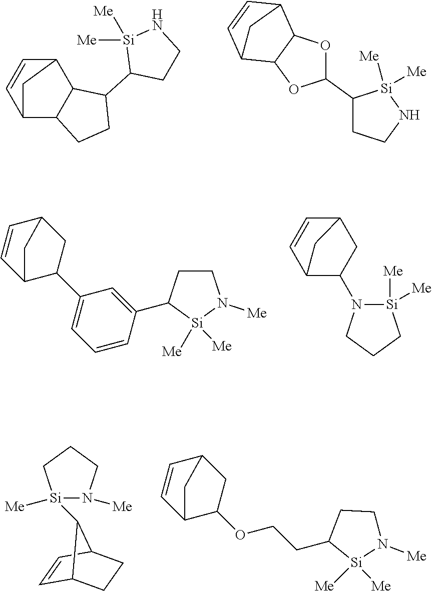

While the formulas and structures depicted herein are shown without any indication of stereochemistry, unless otherwise specified, the norbornene compounds described herein are comprised of diastereomeric mixtures that generally retain their configuration upon reaction of the double bond by the manners described below. The diagram below depicts, as representative, the R and S enantiomers of exo and endo isomers of an inventive norbornene structure that results from two non-identical groups being attached to the C4 or C5 carbon of the norbornene. As these exo and endo isomers and their enantiomers can have different properties, it should be understood that it is within the scope of the disclosure to take advantage of such differences by utilizing essentially pure exo or endo isomer, or R or S enantiomers, or mixtures rich in either isomer or enantiomer.

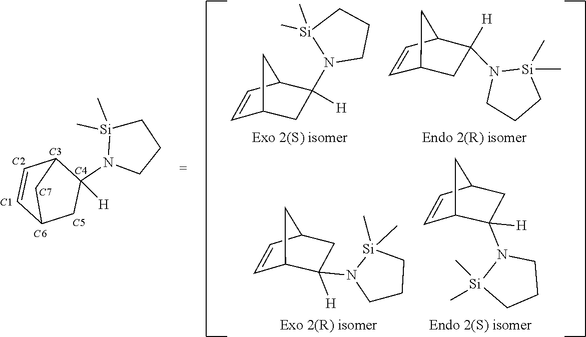

### Surface Functionalization

Further embodiments of the disclosure relate to the functionalization of surfaces with norbornene groups in a rapid, VOC-free or low-VOC manner by utilizing appropriate heterocyclic groups that undergo ring-opening reactions with the hydroxide groups of the target substrates.

More specifically, aspects of the disclosure relate to the attachment of the norbornene compounds described herein to: (a) substrates which comprise hydroxide surface groups such as glass, quartz, alumina, and titania; (b) polymer substrates that inherently have hydroxide groups on their surfaces as part of their chemistry, such as epoxies or urethanes; or (c) substrates which are treated to provide surface hydroxyl groups by utilizing techniques such as the treatment of silicones, polyesters, polystyrene, butadiene rubbers, polyethylene, or polypropylene with oxidative processes such as ozone, ozone/UV, plasma or corona.

It is known in the art that norbornene groups can be attached to such substrates through the use of trialkoxysilyl functional norbornenes such as [(5-bicyclo[2.2.1]hept-2-enyl)ethyl]trimethoxysilane. However, the reaction rates of such molecules are low, requiring times on the scale of one hour as well as elevated deposition temperatures of around 100° C. to achieve sufficient coverage for most applications. In addition, a post-curing step of around one hour at 100° C. is often required to further condense the remaining alkoxy groups into a final stable state. Furthermore, exposure to these compounds often results in excess material being physisorbed on the substrate surface, which requires further processing to remove before the curing step. Additionally, the reactive chemistry of the deposition process involves the generation of a volatile organic component, in this case methanol, which results further in process safety and environmental concerns.

However, it has been found that the norbornene heterocyclic compounds as described herein, containing norbornene which is chemically bonded to a heterocyclic compound with bonds between Group 14 and either Group 15 or Group 16 elements, rapidly ring-open in the presence of hydroxide groups and may be used to attach a norbornene functionality to a hydroxide-containing substrate without the concomitant release of a VOC.

It should be understood that the use of inventive heterocyclic compounds, upon reaction with a hydroxylated surface, do so without the release of any volatile organic compounds (VOC) such as methanol or ethanol. If the inventive heterocyclic compound contains no alkoxide or other reactive groups, the use of this compound in the inventive process will be VOC-free. If, however, the inventive molecule does contain alkoxy groups or other reactive groups capable of secondary reactions, VOCs may be released upon their reaction or cure. In this case, the inventive process is VOC-reduced relative to comparative processes, which release alcohol upon the initial reaction with the substrate as well as upon subsequent reaction or cure.

A method for forming a norbornene functional surface according to aspects of the disclosure therefore comprises exposing a substrate comprising hydroxide surface groups to a norbornene compound as described herein. The exposure may be vapor phase exposure by any means known in the art, such as, for example, chemical vapor deposition, and is performed below about 80° C., or more preferably below about 50° C., and most preferably below about 30° C. on time scales less than about one hour by exposing the substrate to vapors of the inventive compound. Liquid phase exposure, in which the norbornene compound may optionally be dissolved in a non-hydrolytic solvent such as toluene, tetrahydrofuran, or dimethoxyethane, may be performed by spin coating, dip coating, wiping, spray coating, or other means known in the art.

Scheme 1 depicts a hydroxylated surface being functionalized with norbornene groups according to such methods.

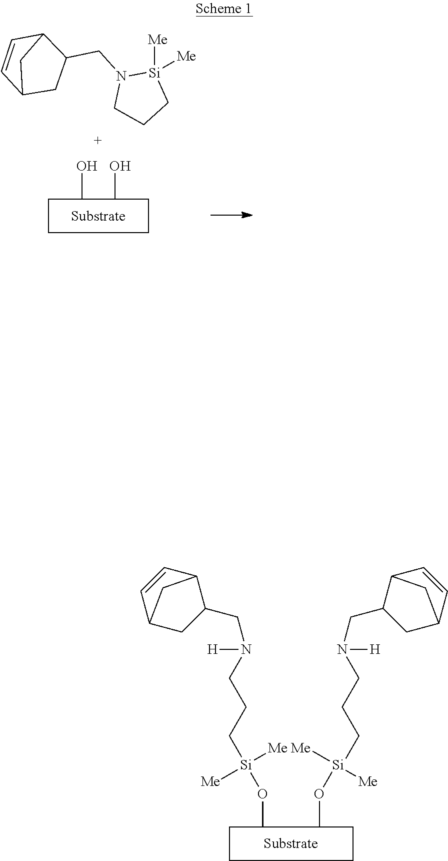 [SMILES: C[Si]1(C)CCCN1CC1CC2C=CC1C2 ; OC1CCCCC1O ; C[Si](C)(CCCNCC1CC2C=CC1C2)OC1CCCCC1O[Si](C)(C)CCCNCC1CC2C=CC1C2]

### Utilization of Norbornene-Functionalized Surfaces as Coupling Agents

In another embodiment of the disclosure, the surfaces coated with the inventive compounds may be used to bind molecules or polymers with reactivity towards norbornene groups. Such molecules or polymers known in the art may comprise reactive groups such as azides, thiols, or tetrazoles, which are known to react with norbornene groups in a rapid “Click” chemistry manner. The norbornene groups may be used to directly attach to an appropriately functionalized molecule of interest, as depicted in Scheme 2, or may be attached to an appropriately functionalized binding layer, which in turn binds an appropriately functionalized target molecule, as depicted in Scheme 3. While not limiting, target molecules may include, for example, molecules designed for the detection, reaction or binding of biomolecules such as nucleic acids, proteins, lipids, or carbohydrates. While not limiting, an appropriate binding layer may comprise a polymer functionalized with multiple azide, thiol, or tetrazole groups.

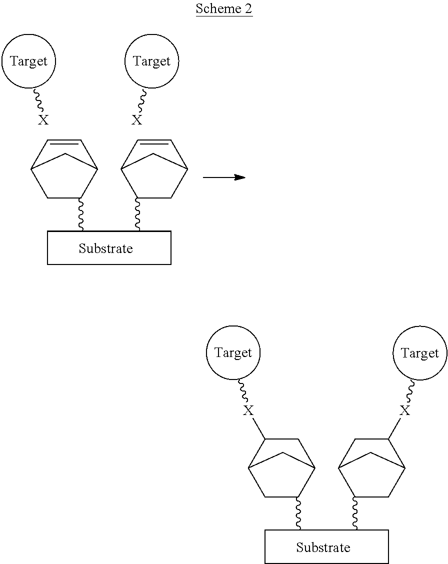

In Scheme 2 and Scheme 3, “X” represents a norbornene-reactive group such as azide, thiol, or tetrazole, while in Scheme 3, “Y” represents a group that is reactive to the norbornene-reactive group, such as norbornene or alkynes.

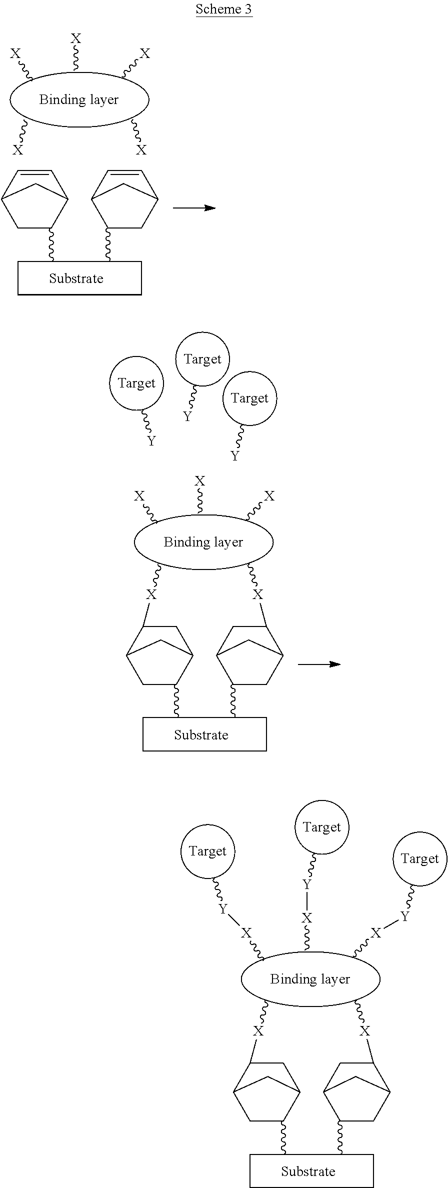

Azide, thiol and tetrazole groups that are appropriate for binding to norbornene-functionalized surfaces are shown below, where R represents an organic or organic/inorganic chemical compound

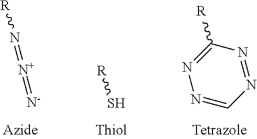

The invention will now be described in connection with the following non-limiting examples.

### Example 1: Synthesis of N-[(Bicyclo[2.2.1]hept-2-enyl)methyl]aza-2,2-dimethoxysilacyclopentane

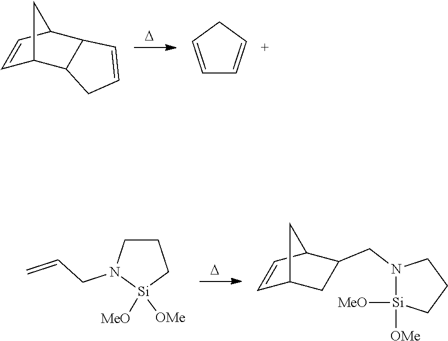

A 1 L 4-neck flask was equipped with magnetic stirrer, pot thermal probe, cooling bath, addition funnel, packed column, and distillation head with N₂. Dicyclopentadiene (495.8 g, 3.75 mol) was charged to reactor and heated to reflux. N-Allyl-aza-2,2-dimethoxysilacyclopentane (1404.8 g, 7.5 mol) was added dropwise to the reaction mixture at a rate to maintain reaction temperature at 170° C. over 1-2 h. The resulting reaction mixture was stirred at 170-180° C. for 72 h. The product is purified by fractional distillation to afford the final product, N-[(5-bicyclo[2.2.1]hept-2-enyl)methyl]aza-2,2-dimethoxysilacyclopentane (NB-CAZ-1), 344 g (18.1%), 99.1% purity.

### Example 2: Deposition of an NB-CAZ-1 Monolayer on a Silicon Dioxide Surface

A silicon wafer coupon with 110 orientation and a native oxide layer was cleaned with oxygen plasma for ten minutes in order to remove organic contamination. The coupon was then placed in a stainless steel vacuum vessel of approximately 250 ml volume and the system evacuated for five minutes at 25° C. The system was then filled with nitrogen and 50 μl of NB-CAZ-1 added to the vessel in a position adjacent to the coupon. The system was then evacuated for one minute, after which the system was isolated from the pumps and allowed to remain under static vacuum at 25° C. for thirty minutes. The coupon was rinsed with ethanol in order to remove any physisorbed material. An organic layer of 1.4 nm thickness was measured by ellipsometry and the presence of 4.2% nitrogen on the surface was confirmed by X-ray photoelectron spectroscopy (XPS).

### Example 3: Attachment of PEG-Azide to the NB-CAZ-1 Functional Surface

8-arm PEG-Azide of approximately 40,000 molecular weight and a hydrodynamic radius of about 4 nanometers was dissolved in a 95/5 solution of water/ethanol at a concentration of 0.5%. A coupon prepared by the method of Example 2 with an area of approximately 5 cm² was coated with 0.4 ml of the PEG-Azide solution, allowed to dry, and then cured at 70° C. for one hour in a drying oven. The coupon was then sonicated for ten minutes in deionized water and then rinsed with deionized water to remove unbound PEG-Azide. An organic layer of 9.25 nm was detected by ellipsometry and the presence of PEG-Azide was confirmed by XPS (62% oxygenated carbon, 33% oxygen, 1% nitrogen, and 4% silicon from the underlying substrate and NB-CAZ-1 layers).

### Example 4: Deposition of an NB-CAZ-1 on an Aluminum Substrate Via Solvent Deposition

0.0415 grams of N-[(5-bicyclo[2.2.1]hept-2-enyl)methyl]aza-2,2-dimethoxysilacyclopentane (NB-CAZ-1) were added to 1.95 grams of dried heptane and this blend was mixed on a FlackTek 330-100 PRO centrifugal mixer at 3500 rpm for 20 seconds. This blend was dispensed in liquid form onto 2024T3 aluminum and wiped with a clean room wipe. Analysis showed a 10 nm thick film containing norbornene via XPS.

### Comparative Example 1: Attachment of PEG-Azide Without NB-CAZ-1

A silicon wafer coupon of approximately 5 cm² was plasma cleaned in the same manner as Example 1. Without exposure to NB-CAZ-1, the coupon was then coated with 8-arm PEG-Azide in accordance with Example 3. No PEG-Azide layer was observed by ellipsometry or XPS.

It will be appreciated by those skilled in the art that changes could be made to the embodiment described above without departing from the broad inventive concepts thereof. Also, based on this disclosure, a person of ordinary skill in the art would further recognize that the relative proportions of the components illustrated above could be varied without departing from the spirit and scope of the invention. It is understood, therefore, that this invention is not limited to that particular embodiment disclosed, but it is intended to cover modifications within the spirit and scope of the present invention as defined by the appended claims.

We claim:

1. A norbornene compound having formula (I), formula (II), formula (III), formula (IV), formula (V) or formula (VI): 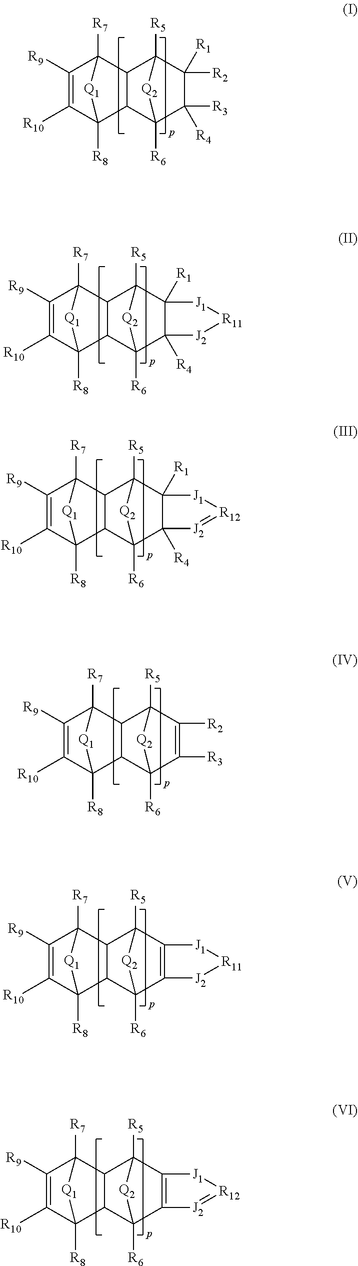
wherein p is 0, 1 or 2; Q₁ and Q₂ are independently O, S, N(R₁₃), C═O, C(R₁₄)(R₁₅) or (R₁₄)(R₁₅)C—C—(R₁₆)(R₁₇); J₁ and J₂ are independently O, S, N(R₁₈), C═O, or C(R₁₉)(R₂₀); J₃ is N or C(R₁₉);
R₁₁ is an (C5-C12)aliphatic group, (C5-C12)heterocyclic group, or (C6-C14)aromatic group bonded to both J₁ and J₂ or has formula [T]: 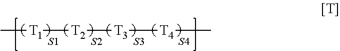
wherein T₁, T₂, T₃, and T₄ are each independently selected from O, S, N(R₂₁), C═O and C(R₂₂)(R₂₃), each of S₁, S₂, S₃, and S₄ is 0 or 1, provided that S₁+S₂+S₃+S₄>0; and wherein if S₁+S₂+S₃+S₄≥2, [T] is a bidentate ligand bonded to both J₁ and J₂;
R₁₂ a (C5-C12)aliphatic group or a (C5-C12)heterocyclic group bonded to both J₃ and J₂ or has formula [U]: 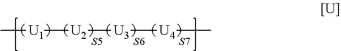
wherein U₁ is N or C(R₂₂); U₂, U₃, and U₄ are each independently selected from O, S, N(R₂₁), C═O and C(R₂₂)(R₂₃) and each of S₅, S₆, and S₇ is 0 or 1; wherein if S₅+S₆+S₇≥1, [U] is a bidentate ligand bonded to both J₁ and J₃;
R₁, R₂, R₃, R₄, R₅, R₆, R₇, R₈, R₉, R₁₀, R₁₃, R₁₄, R₁₅, R₁₆, R₁₇, R₁₈, R₁₉, R₂₀, R₂₁, R₂₂ and R₂₃ are the same or different and are each independently selected from the group consisting of a single bond, hydrogen, halogen, hydroxy, methyl, ethyl, methoxy, ethoxy, linear or branched (C₃-C₁₈)alkyl, (C₂-C₁₈)alkenyl, (C₃-C₁₈)alkoxy, tri(C₁-C₆)alkylsilyl, tri(C₁-C₆)alkoxysilyl, di(C₁-C₆)alkylamino, di(C₁-C₆)alkyl(C₁-C₆)alkylamino, perfluoro(C₁-C₁₈)alkyl, (C₃-C₁₂)cycloalkyl, (C₆-C₁₂)bicyclo(C₁-C₆)alkyl, (C₇-C₁₄)tricyclo(C₁-C₆)alkyl, (C₁-C₁₈)thioalkyl, (C₂-C₆)acyl, (C₂-C₈)acyloxy, (C₆-C₁₄)aryl, (C₆-C₁₄)aryl(C₁-C₈)alkyl, perfluoro(C₆-C₁₄)aryl, perfluoro(C₆-C₁₄)aryl(C₁-C₃)alkyl, (C₆-C₁₄)aryloxy, (C₆-C₁₄)aryl(C₁-C₆)alkoxy, (C₁-C₁₂)alkyl(C₁- C₁₂)perfluoro, and at least one of R₁, R₂, R₃, R₄, R₅, R₆, R₇, R₈, R₉, R₁₀, R₁₃, R₁₄, R₁₅, R₁₆, R₁₇, R₁₈, R₁₉, R₂₀, R₂₁, R₂₂ and R₂₃ comprises or is substituted with a heterocyclic group having formula (A), formula (B), formula (C), formula (D), formula (E), formula (F), formula (G), or formula (H): 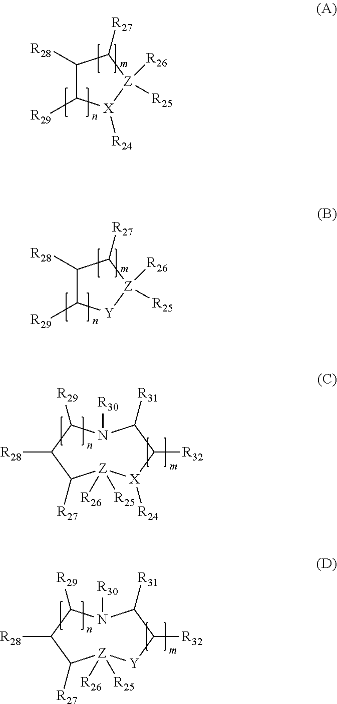 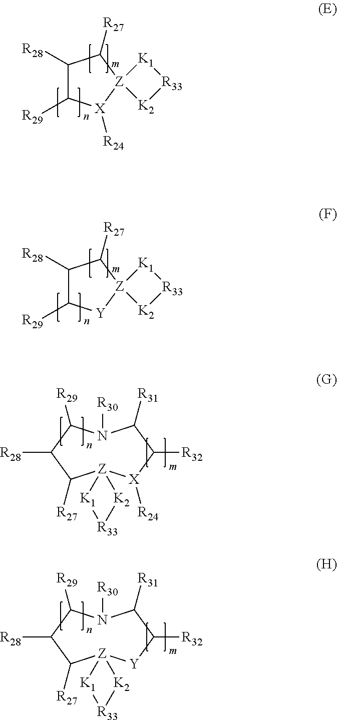
wherein Z is a Group 14 element other than carbon; X is a Group 15 element; Y is a Group 16 element; m and n are each independently an integer from 1 to 10; K₁ and K₂ are independently O, S, N(R₃₄), or C(R₃₅)(R₃₆); R₃₃ is an (C5-C12)aliphatic group, a (C5-C12)heterocyclic, a (C6-C14)aromatic group bonded to both J₁ and J₂, or has formula [W]: 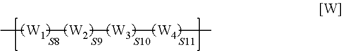
wherein W₁, W₂, W₃, and W₄ are each independently selected from O, S, N(R₃₇), C═O and C(R₃₉)(R₃₉), each of S₈, S₉, S₁₀, and S₁₁ is 0 or 1, provided that S₈+S₉+S₁₀+S₁₁>0; wherein if S₈+S₉+S₁₀+S₁₁≥2, [W] is a bidentate ligand bonded to both K₁ and K₂;
R₂₄, R₂₅, R₂₆, R₂₇, R₂₈, R₂₉, R₃₀, R₃₁, R₃₂, R₃₄, R₃₅, R₃₆, R₃₇, R₃₈, and R₃₉ are the same or different and are each independently a single bond, hydrogen, halogen, hydroxy, methyl, ethyl, methoxy, ethoxy, linear or branched (C₃-C₁₈)alkyl, (C₂-C₁₈)alkenyl, (C₃-C₁₈)alkoxy, tri(C₁-C₆)alkylsilyl, tri(C₁-C₆)alkoxysilyl, di(C₁-C₆)alkylamino, di(C₁-C₆)alkyl(C₁-C₆)alkylamino, perfluoro(C₁-C₁₈)alkyl, (C₃-C₁₂)cycloalkyl, (C₆-C₁₂)bicyclo(C₁-C₆)alkyl, (C₇-C₁₄)tricyclo(C₁-C₆)alkyl, (C₁-C₁₈)thioalkyl, (C₂-C₆)acyl, (C₂-C₈)acyloxy, (C₆-C₁₄)aryl, (C₆-C₁₄)aryl(C₁-C₈)alkyl, perfluoro(C₆-C₁₄)aryl, perfluoro(C₆-C₁₄)aryl(C₁-C₃)alkyl, (C₆-C₁₄)aryloxy, (C₆-C₁₄)aryl(C₁-C₆)alkoxy, or (C₁-C₁₂)alkyl(C₁-C₁₂)perfluoro; where at least one of R₂₄, R₂₅, R₂₆, R₂₇, R₂₈, R₂₉, R₃₀, R₃₁, R₃₂, R₃₄, R₃₅, R₃₆, R₃₇, R₃₈, and R₃₉ is a single bond connecting to a structure of formula (I), formula (II), formula (III), formula (IV), formula (V) or formula (VI).

2. The norbornene compound according to claim 1, wherein Z is silicon or germanium.

3. The norbornene compound according to claim 1, wherein X is nitrogen.

4. The norbornene compound according to claim 1, wherein Y is sulfur, selenium, or tellurium.

5. The norbornene compound according to claim 1, wherein p=0, m=1, and n=1.

6. The norbornene compound according to claim 1, wherein R₂₄ is a single bond, hydrogen, methyl, ethyl, vinyl, isopropyl, n-propyl, allyl, n-butyl, sec-butyl, or t-butyl, R₂₅ and R₂₆ are a single bond, hydrogen, methyl, methoxy, or ethoxy, R₂₇, R₂₈, R₂₉, R₃₀, R₃₁, and R₃₂ are independently a single bond, hydrogen, or methyl, Z is silicon, and X is nitrogen or Y is sulfur.

7. The norbornene compound according to claim 1, wherein the compound is N-[(bicyclo[2.2.1]hept-2-enyl)methyl]aza-2,2-dimethoxysilacyclopentane or -[(bicyclo[2.2.1]hept-2- enyl)methyl]aza-2,2-diethoxysilacyclopentane

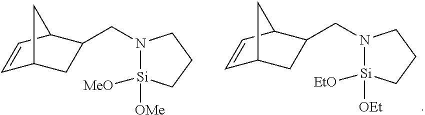

8. The norbornene compound according to claim 1, having a structure selected from:

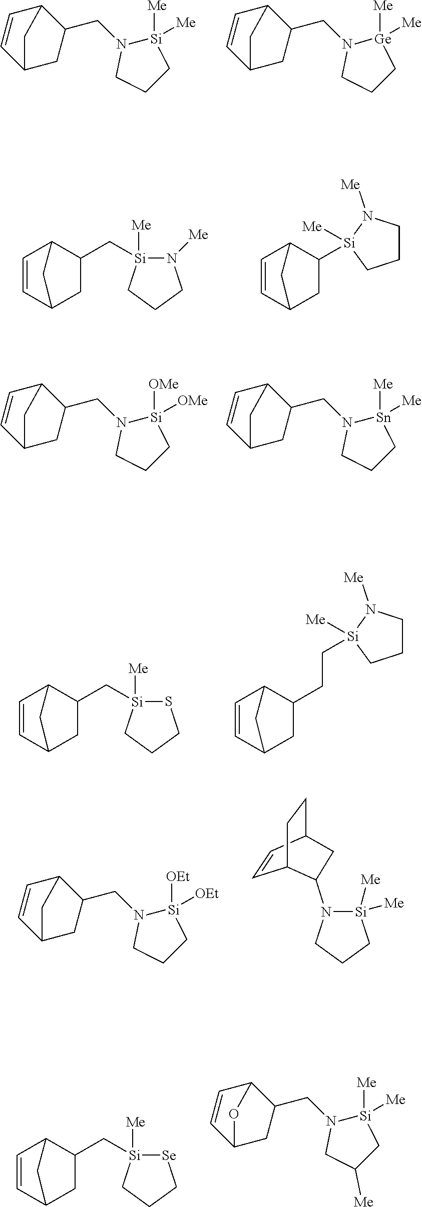

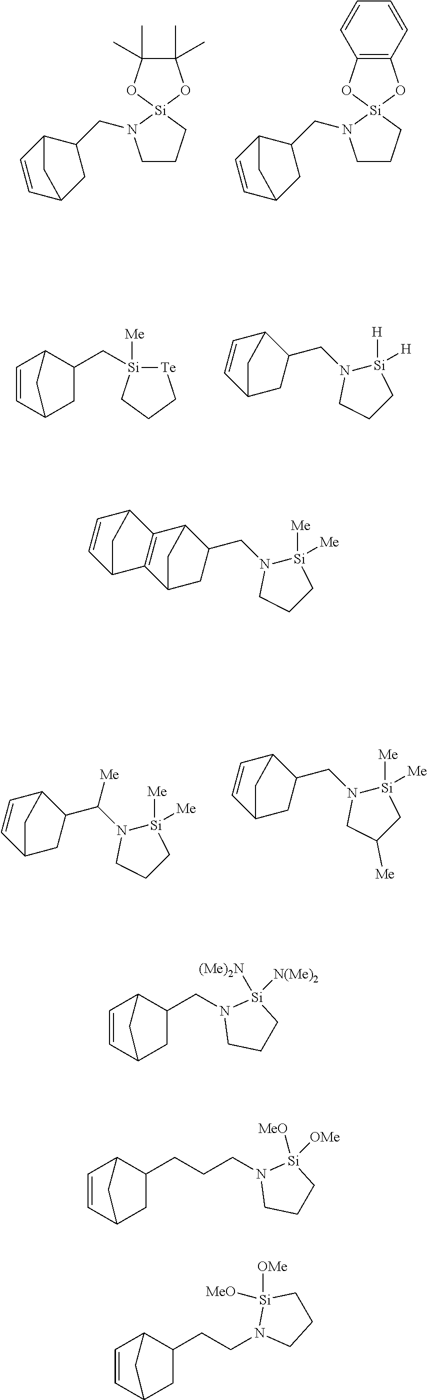

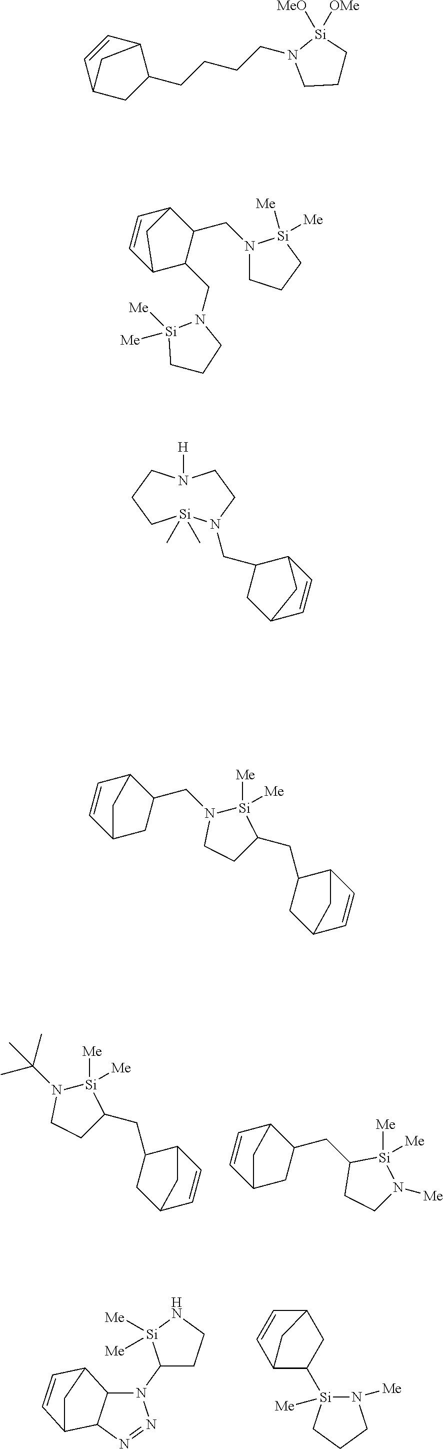

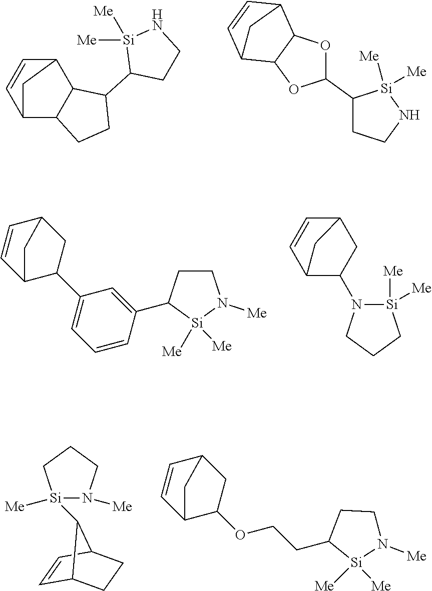

9. A method for forming a norbornene functional surface, comprising exposing a substrate comprising hydroxide surface groups to a norbornene compound according to claim 1.

10. The method according to claim 9, comprising vapor phase exposure of the norbornene compound to the substrate.

11. The method according to claim 10, where the vapor phase exposure is performed below about 80° C.

12. The method according to claim 11, wherein the vapor phase exposure is performed below about 50° C.

13. The method according to claim 12, wherein the vapor phase exposure is performed below about 30° C.

14. The method according to claim 9, comprising liquid phase exposure of the norbornene compound to the substrate.

15. The method according to claim 14, wherein the liquid phase exposure comprises spin coating, dip coating, applying by wiping the liquid on the substrate, or spray coating.

16. A method of forming a reactive polymer layer bound to a substrate, the method comprising coating the norbornene functional surface according to claim 9 with a polymer comprising norbornene-reactive functional groups.

17. The method according to claim 16, where the polymer comprising norbornene-reactive functional groups comprises azide, thiol, or tetrazine functional groups.

18. The method according to claim 16, where the polymer comprising norbornene-reactive functional groups is coated on the norbornene functional surface via spin coating, dip coating, applying by wiping the liquid on the substrate, or spray coating.
